(19) United States
(12) Patent Application Publication
(10) Pub. No.: US 2024/0243097 A1
(43) Pub. Date: Jul. 18, 2024

(54) POWER MODULE PACKAGE STRUCTURE

(71) Applicant: Industrial Technology Research Institute, Hsinchu (TW)

(72) Inventors: Yu-Ming Peng, Taichung City (TW); I-Hung Chiang, Hsinchu City (TW); Chun-Kai Liu, Hsinchu City (TW); Po-Kai Chiu, Taoyuan City (TW); Hsin-Han Lin, Hsinchu County (TW); Kuo-Shu Kao, Hsinchu County (TW)

(73) Assignee: Industrial Technology Research Institute, Hsinchu (TW)

(21) Appl. No.: 18/415,677

(22) Filed: Jan. 18, 2024

Related U.S. Application Data
(60) Provisional application No. 63/439,582, filed on Jan. 18, 2023.

(30) Foreign Application Priority Data
Dec. 19, 2023 (TW) 112149388

(51) Int. Cl. H01L 25/065; H01L 23/00; H01L 23/31; H01L 23/498

(52) U.S. Cl. CPC H01L 25/0655; H01L 23/3121; H01L 23/49838; H01L 24/16; H01L 24/32; H01L 24/48; H01L 24/73; H01L 2224/16225; H01L 2224/32225; H01L 2224/48155; H01L 2224/73253; H01L 2224/73265; H01L 2924/181

(57) ABSTRACT

A power module package structure includes a first substrate and a power component. The first substrate includes at least one conductive layer on a surface thereof. The power component includes a first chip and a first spacer. The first chip has at least one electrode. The first spacer in a heat dissipation space between the first substrate and the first chip includes an insulating heat dissipation layer in the heat dissipation space and multiple vertical conductive connectors, each of the vertical conductive connectors penetrates the insulating heat dissipation layer. The insulating heat dissipation layer surrounds the vertical conductive connectors and electrically isolates the vertical conductive connectors. The vertical conductive connector includes two opposite ends, one end electrically connected to the conductive layer, and the other end electrically connected to the electrode to form a conductive path and a heat dissipation path between the first chip and the first substrate.

### CROSS-REFERENCE TO RELATED APPLICATION

This application claims the priority benefits of U.S. provisional application Ser. No. 63/439,582, filed on Jan. 18, 2023 and Taiwan application Ser. No. 11/214,9388, filed on Dec. 19, 2023. The entirety of the above-mentioned patent application is hereby incorporated by reference herein and made a part of this specification.

### TECHNICAL FIELD

The disclosure relates to a power module package structure.

### BACKGROUND

As a power module package structure develops towards high power, thinness, and high density, requirements for all aspects thereof are becoming increasingly stringent. For example, as functions of a power chip have been greatly improved, heat generated during operation has also increased. If a heat dissipation capacity of the power module package structure may not be effectively improved to remove waste heat, it will easily cause adverse effects on the power chip.

### SUMMARY

An embodiment of the disclosure provides a power module package structure, including a first substrate and a power component. The first substrate includes at least one conductive layer located on a surface thereof. The power component includes a first chip and a first spacer. The first chip has at least one electrode. The first spacer is located in a heat dissipation space between the first substrate and the first chip, and includes an insulating heat dissipation layer and multiple vertical conductive connectors. The insulating heat dissipation layer is located in the heat dissipation space. Each of the vertical conductive connectors penetrates the insulating heat dissipation layer. The insulating heat dissipation layer surrounds the vertical conductive connector and electrically isolates the vertical conductive connector. The vertical conductive connector includes two opposite ends. One end is electrically connected to the conductive layer, and the other end is electrically connected to the electrode to form a conductive path and a heat dissipation path between the first chip and the first substrate.

An embodiment of the disclosure provides a power module package structure, including a first substrate and a power component located on the first substrate. The power component includes a first chip and a spacer connecting the first chip and the first substrate. The spacer includes multiple vertical conductive connectors and an insulating heat dissipation layer. The insulating heat dissipation layer is located in a heat dissipation space between the first substrate and the first chip and surrounds the vertical conductive connector to electrically isolate the vertical conductive connectors. The vertical conductive connectors penetrate the insulating heat dissipation layer to be electrically connected to the first chip and the first substrate.

An embodiment of the disclosure provides a power module package structure, including a conductive layer, a first substrate, and a power component. The first substrate is located at a position opposite to the conductive layer. The power component is located on the first substrate and includes a chip, at least one pin, a first spacing portion, and a second spacing portion. The chip is located in a heat dissipation space between the conductive layer and the first substrate. The at least one pin is electrically connected to the chip. The first spacing portion is adjacent to the chip, and includes multiple vertical conductive connectors electrically connected to the pin and an insulating heat dissipation layer surrounding the vertical conductive connectors. The vertical conductive connectors penetrate the insulating heat dissipation layer to form a conductive path between the chip and the first substrate. The second spacing portion is located on the chip, and includes multiple vertical conductive connectors electrically connected to the chip and the conductive layer and an insulating heat dissipation layer surrounding the vertical conductive connectors. The vertical conductive connectors penetrate the insulating heat dissipation layer to form a heat dissipation path between the conductive layer and the chip.

In order for the aforementioned features and advantages of the disclosure to be more comprehensible, embodiments accompanied with drawings are described in detail below

### BRIEF DESCRIPTION OF THE DRAWINGS

FIG. 1A is a schematic cross-sectional view of a power module package structure according to an embodiment of the disclosure.

FIG. 1B is a schematic partial cross-sectional view of the power module package structure in FIG. 1A.

FIG. 1C is another schematic partial cross-sectional view of the power module package structure in FIG. 1A.

FIG. 1D is still another schematic partial cross-sectional view of the power module package structure in FIG. 1A.

FIG. 2 is a schematic top view of a spacer in FIG. 1.

FIG. 3 is a schematic bottom view of an electrode of a chip in FIG. 1.

FIG. 4 is a schematic top view of a wiring line of a substrate in FIG. 1.

FIG. 5 is a schematic view of a circuit of a power module package structure according to some embodiments of the disclosure.

FIGS. 6, 7, 8, and 9 are schematic cross-sectional views of power module package structures according to some embodiments of the disclosure.

FIG. 10 is a schematic view of thermal conductivity versus average linear coefficient of thermal expansion of some materials.

FIGS. 11A and 11B are schematic views of spacers according to some embodiments of the disclosure.

### DETAILED DESCRIPTION OF DISCLOSED EMBODIMENTS

Herein, describing a first component as being similar to a second component means that it may have similar material selection, structural design, function, and/or configuration.

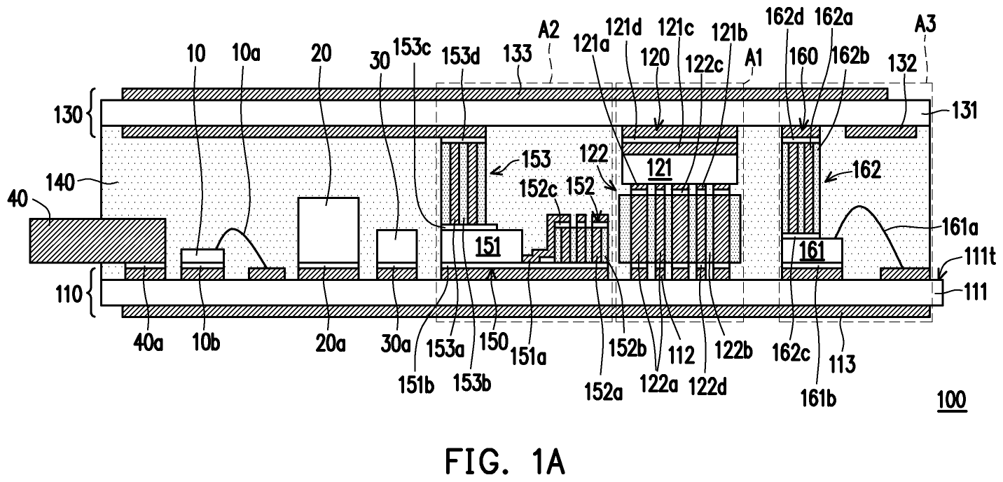

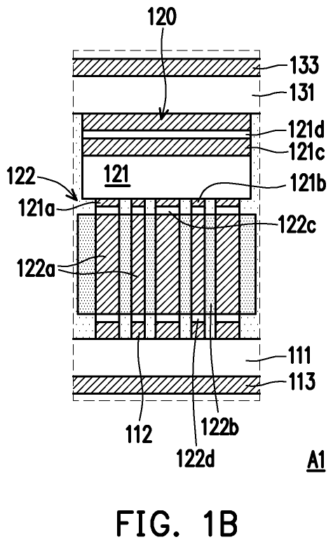

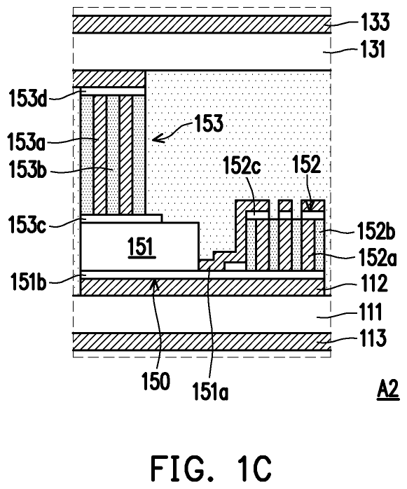

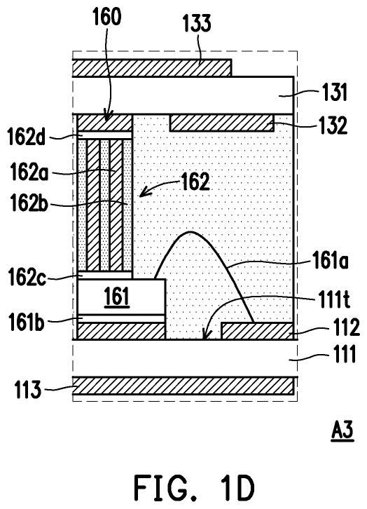

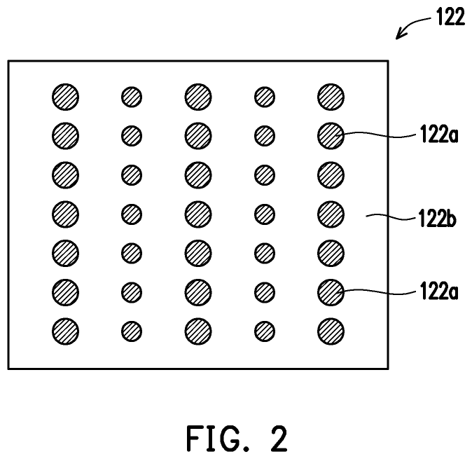

Referring to FIGS. 1A and 2 together, a power module package structure 100 in this embodiment includes a first substrate 110 and a first power component 120 located on the first substrate 110. The first substrate 110 includes a first conductive layer 112 located on a surface thereof (e.g., a top surface 111t of a core layer 111). In addition, the first power component 120 includes a first chip 121 and a first spacer 122 connecting the first chip 121 and the first substrate 110.

In this embodiment, the first spacer 122 includes multiple first vertical conductive connectors 122a and a first insulating heat dissipation layer 122b. The first vertical conductive connector 122a is formed by one or more arbitrary combinations of metal elements, such as molybdenum (Mo), copper (Cu), silver (Ag), and nickel (Ni), and the first vertical conductive connector 122a may further be one or more metal pillars (circular metal pillars as shown in FIG. 2). A thickness of each of the metal pillars is between 0.1 millimeters (mm) and 2 mm (e.g., 1 mm). In addition, the first insulating heat dissipation layer 122b is formed by insulating organic materials. The insulating organic materials include ceramic materials or doped ceramic materials, such as aluminum nitride (AlN), copper molybdenum (CuMo), aluminum silicon carbide (AlSiC), aluminum oxide (Al₂O₃), silicon nitride (Si₃N₄), or a combination thereof, and the first insulating heat dissipation layer 122b may also be configured to surround and electrically isolate the first vertical conductive connector 122a.

In addition, the first chip 121 has a first electrode 121a and a second electrode 121b, and the first spacer 122 is located in a heat dissipation space between the first substrate 110 and the first chip 121. In this way, the first insulating heat dissipation layer 122b may be located in the heat dissipation space to form a heat dissipation path between the first substrate 110 and the first chip 121. In addition, the first vertical conductive connector 122a penetrates the first insulating heat dissipation layer 122b, and one end thereof is electrically connected to the first conductive layer 112, while another end thereof is electrically connected to the first electrode 121a and the second electrode 121b to form a conductive path between the first substrate 110 and the first wafer 121. Therefore, when the first spacer 122 may be electrically connected to the first chip 121 and thermally conductive with the first chip 121, a signal of the first chip 121 may be transmitted to the first substrate 110 through the first spacer 122, and heat generated when the first chip 121 operates may also be transmitted to the first substrate 110 through the first spacer 122. In addition, when an orthogonal projection of the first spacer 122 on the first substrate 110 overlaps an orthogonal projection of the first chip 121 on the first substrate 110, for example, the first vertical conductive connector 122a, the first conductive layer 112, the first electrode 121a, and the second electrode 121b are aligned with one another in a direction perpendicular to the top surface 111t of the first substrate 110, the signal and heat of the first chip 121 are transmitted through the first spacer 122 in the direction perpendicular to the top surface 111t of the first substrate 110. Here, the first chip 121 may be in a form of a bare crystal. That is, the chip 121 is not covered by a package colloid when bonded to the substrate 110.

In some embodiments, the first substrate 110 is a direct bonded copper (DBC) ceramic substrate that has both conductive and heat dissipation functions. The first substrate 110 includes the first core layer 111 as well as the first conductive layer 112 and a second conductive layer 113 disposed on two opposite sides thereof (materials of the first and second conductive layers 112 and 113 are, for example, copper), and the first conductive layer 112 faces the first spacer 122. In addition, a thickness of the first conductive layer 112 may further be adjusted accordingly according to a diameter of the first vertical conductive connector 122a. Experimental data shows that when the thickness of the first conductive layer 112 is half a diameter of the metal pillar (the first vertical conductive connector 122a), coefficients of thermal expansion (CTE) of the first substrate 110 and the first power component 120 (including the first chip 121 and the first spacer 122) may be optimized and matched with each other. For example, if the diameter of the metal pillar (the first vertical conductive connector 122a) is 0.5 mm, the thickness of the first conductive layer 112 is 0.25 mm. This is an exemplary illustration, and the conditions may be adjusted according to actual design requirements.

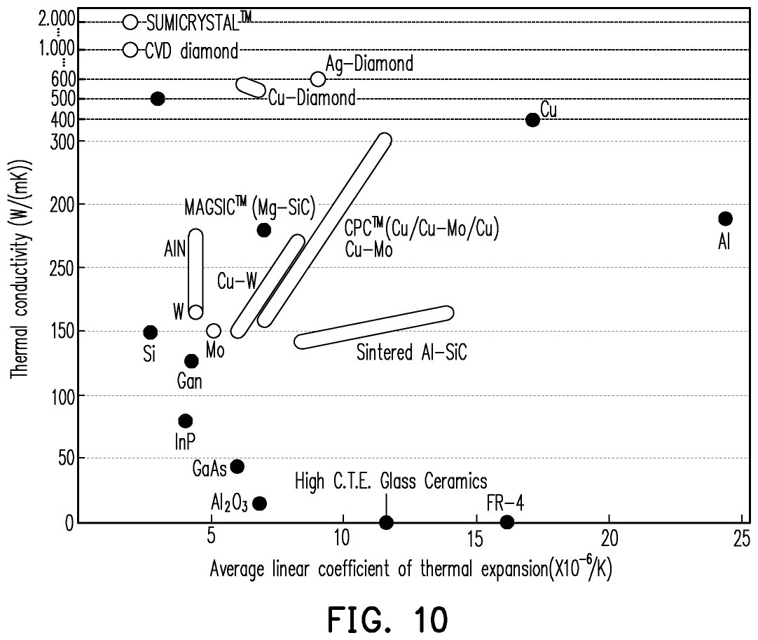

Referring to FIG. 10, in some embodiments, the experimental data shows that when insulating materials, such as aluminum nitride, copper molybdenum, and aluminum silicon carbide are used for the first insulating heat dissipation layer 122b, coefficients of thermal expansion (CTE) of the first vertical conductive connection member 122a and the first insulating heat dissipation layer 122b may be optimized and matched with each other through material properties in FIG. 10 to achieve better thermal conductivity. For example, when the first insulating heat dissipation layer 122b is aluminum nitride, the thermal conductivity is 170 W/mK at a temperature of 20° C., and the coefficient of thermal expansion may be reduced to 4.7 ppm/K. This is an exemplary illustration, and the conditions may be adjusted according to the actual design requirements.

In some embodiments, a thickness of the core layer 111 is between 0.1 mm and 1 mm (e.g., 0.25 mm). The diameter of the metal pillar is between 0.2 mm and 2 mm (e.g., 0.5 mm). The thicknesses of the first conductive layer 112 and the second conductive layer 113 is between 0.1 mm and 1 mm (e.g., 0.3 mm).

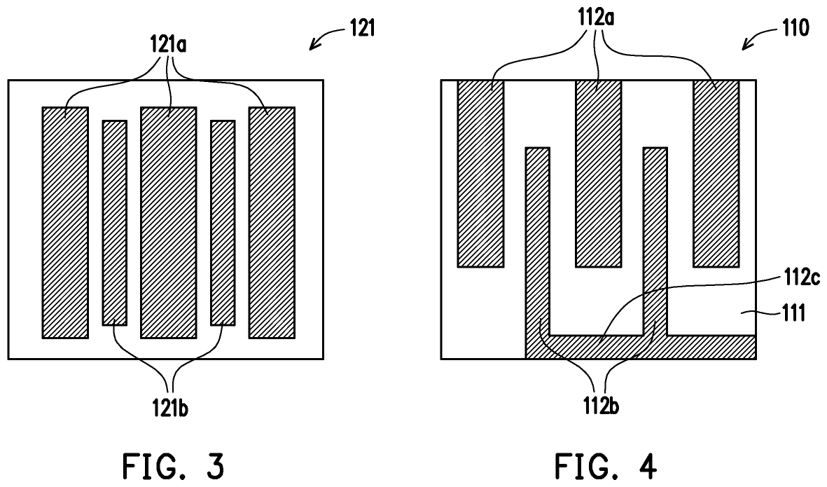

In this embodiment, when the first vertical conductive connector 122a is in a form of multiple metal pillars, it may be attached to multiple electrodes with different polarities on the first chip 121. In this way, the first spacer 122 may be electrically connected and thermally conductive to the electrodes with different polarities on the first chip 121 to form multiple channels of composite polarity signals. For example, as shown in FIG. 3, the first chip 121 has the first electrode 121a of different polarities (e.g., an emitter) and the second electrode 121b (e.g., a base or other suitable combinations of different polarities), and multiple portion of the first vertical conductive connector 122a shown in FIG. 1 are electrically connected to the first electrode 121a and the second electrode 121b respectively. In addition, as shown in FIG. 4, a first wiring line 112a of the first conductive layer 112 on the first substrate 110 may be connected to the first electrode 121a correspondingly. A second wiring line 112b of the first conductive layer 112 on the first substrate 110 may be connected to the second electrode 121b correspondingly, and there is a serial connected wiring line 112c between the second wiring lines 112b. A distribution density (metal proportion) of the wiring line of the first conductive layer 112 on the first substrate 110 may also be adjusted to optimize heat dissipation efficiency.

FIG. 3 shows that a size of the first electrode 121b is less than a size of the second electrode 121a, and FIG. 4 shows that the first conductive layer 112 of the first substrate 110 is an interdigitated layout of the wiring line. However, in the embodiment not shown, according to the actual design requirements, the electrode may have different sizes, and the substrate may also have other layouts of the wiring line.

As an exemplary bonding method, the first spacer 122 may include a first bonding layer 122c, and the first bonding layer 122c is bonded to the first chip 121 and in direct contact with the first chip 121, so that the first spacer 122 is attached to the first chip 121. A material of the first bonding layer 122c is, for example, solder. The solder may include tin, silver, copper, lead, or a combination thereof to have both conductive and heat dissipation functions to form electrical connection and heat conduction. A thickness of the first bonding layer 122c is between 0.05 mm and 0.2 mm (e.g., 0.1 mm).

On the other hand, the first spacer 122 may also include a second bonding layer 122d, so that a side thereof opposite to the first chip 121 may be bonded to and in direct contact with the first conductive layer 112 of the first substrate 110, and be electrically connected and thermally conducted to the first conductive layer 112 of the first substrate 110 through the second bonding layer 122d. The second bonding layer 122d is similar to the first bonding layer 122c. Therefore, the same details will not be repeated in the following.

The above first bonding layer 122c and second bonding layer 122d may be omitted according to the actual design requirements. For example, a direct bonding process may be used to achieve effects of electrical connection and heat conduction, and any of the following bonding layers may be omitted in a similar manner. Therefore, the same details will not be repeated in the following.

Referring to FIG. 1A, in order to further improve the heat dissipation efficiency, the power module package structure 100 may further include a second substrate 130. The first power component 120 (the first chip 121 and the first spacer 122) is located between the first substrate 110 and the second substrate 130, and a side of the first chip 121 opposite to the first spacer 122 is electrically connected and thermally conducted to the second substrate 130. In this way, the heat generated by the first chip 121 may achieve a double-sided heat dissipation effect through the first substrate 110 and the second substrate 130, so that the heat generated by the first chip 121 may be dissipated more effectively. Here, the second substrate 130 is similar to the first substrate 110. That is, the second substrate 130 includes a second core layer 131 as well as a third conductive layer 132 and a fourth conductive layer 133 disposed on two opposite sides thereof, and the third conductive layer 132 faces the first spacer 122. As an example, a thermal resistance range of a current single-sided cooling method will be as high as 0.2 K/W to 0.8 K/W, while current double-sided cooling (such as through a design of a thermal interface material (TIM)) may reduce the above thermal resistance by about 50%.

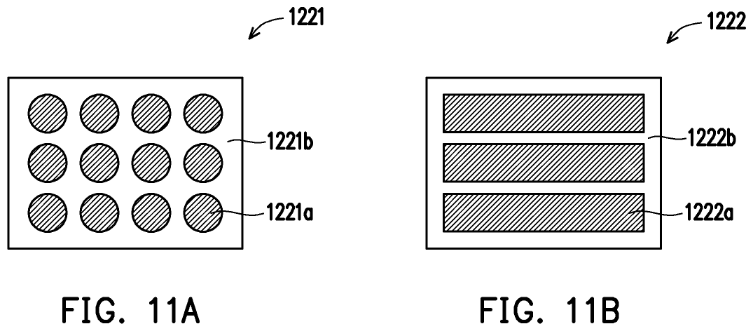

Referring to FIGS. 11A and 11B, when the same metal is used as the conductive connector, a heat dissipation capacity may be further improved by 15% from a spacer 1221 with a small area in FIG. 11A to a spacer 1222 with a large area in FIG. 11B. The spacer 1221 with the small area includes multiple circular metal pillars 1221a and an insulating heat dissipation material 1221b surrounding the circular metal pillars 1221a, while the spacer 1222 with the large area includes multiple strip metal pillars 1222a and an insulating heat dissipation material 1222b surrounding the metal pillars 1222a.

In addition, the first chip 121 has a double-sided electrode structure, and a third electrode 121c thereof opposite to a side of the first spacer 122 may be electrically connected and thermally conducted to the second substrate 130 through a third bonding layer 121d. The third bonding layer 121d is similar to the first bonding layer 122c. Therefore, the same details will not be repeated in the following.

In FIG. 1, the power module package structure 100 further includes a package colloid 140 that encapsulates the first power component 120 (the first chip 121 and the first spacer 122), the first conductive layer 112 of the first substrate 110, and the third conductive layer 132 of the second substrate 130. An edge of the package colloid 140 may be flush with an edge of the first core layer 111 of the first substrate 110 and/or an edge of the second core layer 131 of the second substrate 130. In addition, the edge of the package colloid 140 may be retracted from the edge of the first core layer 111 of the first substrate 110 and/or the edge of the second core layer 131 of the second substrate 130. Here, the package colloid 140 is a molding compound or the like.

The power module package structure 100 further includes a second power component 150 located on the substrate 110. The second power component 150 includes a second chip 151, a first spacing portion 152, and a second spacing portion 153. the package colloid 140 encapsulates the second power component 150 (e.g., the second chip 151, the first spacing portion 152, and the second spacing portion 153) and the first conductive layer 112 thereon, and the second power component 150 is located in a heat dissipation space of the third conductive layer 132 and the first substrate 110. Here, the second chip 151 may be in a form of a discrete component, and therefore may have multiple pins 151a electrically connected to the second chip 151. In addition, the first spacing portion 152 may be connected to the pin 151a and form a conductive path between the second chip 151 and the first substrate 110, while the second spacing portion 153 is located on the second chip 151 and forms a heat dissipation path of the second chip 151.

In this embodiment, the first spacing portion 152 is electrically connected to the second chip 151, and the second spacing portion 153 performs thermal conduction between the third conductive layer 132 and the second chip 151. Furthermore, there is no thermal conduction between the first spacing portion 152 and the second chip 151, and there is no electrical connection between the second spacing portion 153 and the second chip 151. That is, the first spacing portion 152 may only have the conductive function, and the second spacing portion 153 may only have the heat dissipation function.

In this embodiment, the first spacing portion 152 is adjacent to the second chip 151, and the first spacing portion 152 and the second spacing portion 153 are connected to different surfaces of the second chip 151. Therefore, the first spacing portion 152 and the second spacing portion 153 are located at different level heights. The first spacing portion 152 and the second spacing portion 153 are similar to the first spacer 122. That is, the first spacing portion 152 includes multiple second vertical conductive connectors 152a and a second insulating heat dissipation layer 152b, and the second spacing portion 153 includes multiple third vertical conductive connectors 153a and a third insulating heat dissipation layer 153b. Therefore, the same details will not be repeated in the following. Here, although the third vertical conductive connector 153a of the second spacing portion 153 has the conductive function, since it has no electrodes or pins connected to the second chip 151, there is no electrical connection between the second spacing portion 153 and the second chip 151.

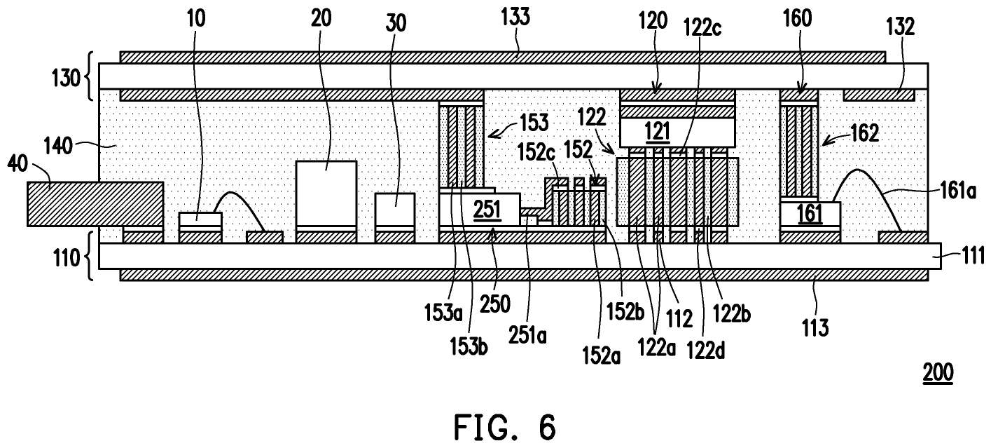

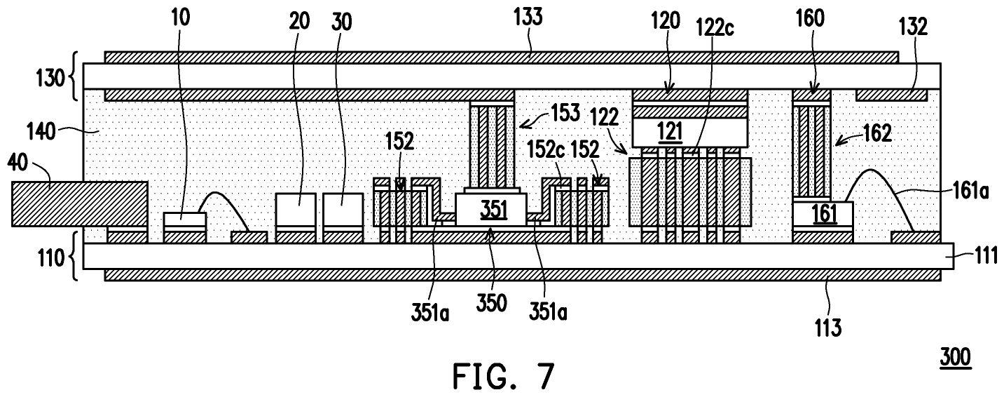

As shown in FIG. 1A, the pin 151a of the second chip 151 of the second power component 150 extends upward (in a direction away from the substrate 110) and is then connected to a fourth bonding layer 152c of the first spacing portion 152, and the pin 151a is a single-sided pin. For example, the second chip 151 may be a TO-263 package structure or the like, but the disclosure is not limited to a form of the pin. Other forms will be further described in the embodiments of FIGS. 6 to 7 in the following. In addition, the second spacing portion 153 may also be bonded to the second chip 151 and the third conductive layer 132 of the second substrate 130 through a fifth bonding layer 153c and sixth bonding layer 153d thereof respectively, and the second chip 151 and the first spacing portion 152 may also be bonded to the first conductive layer 112 of the first substrate 110 through a seventh bonding layer 151b at the same time. Here, the fourth bonding layer 152c, the fifth bonding layer 153c, the sixth bonding layer 153d, and the seventh bonding layer 151b are similar to the first bonding layer 122c. Therefore, the same details will not be repeated in the following.

In this embodiment, the power module package structure 100 further includes a third power component 160 located on the first substrate 110. The third power component 160 includes a third chip 161 and a third spacer 162 located between the third chip 161 and the second substrate 130, and the third spacer 162 forms a conductive path and a heat dissipation path between the third chip 161 and the second substrate 130. Here, the third spacer 162 is similar to the first spacer 122. That is, the third spacer 162 includes multiple fourth vertical conductive connectors 162a and a fourth insulating heat dissipation layer 162b. Therefore, the same details will not be repeated in the following. In addition, in the third power component 160, the third chip 161 may be electrically connected to the first substrate 110 through a first wire bonder 161a, and the package colloid 140 also encapsulates the third chip 161 as well as the first wire bonder 161a and the third spacer 162 thereon.

On the other hand, the third spacer 162 may be electrically connected and thermally conducted to the third chip 161 and the third conductive layer 132 of the second substrate 130 through an eighth bonding layer 162c and a ninth bonding layer 162d respectively, and the third chip 161 may also be bonded to the first conductive layer 112 of the first substrate 110 through a tenth bonding layer 161b. The eighth bonding layer 162c, the ninth bonding layer 162d, and the tenth bonding layer 161b are similar to the first bonding layer 122c. Therefore, the same details will not be repeated in the following.

In FIG. 1A, in order to increase functionality of the power module package structure 100, multiple components with different characteristics may be integrated. For example, an active device 10 (e.g., a driver IC electrically connected to the substrate 110 through a second wire bonder 10a), a sensing element 20 (a temperature sensing element, a current sensing element, etc.), and a passive device 30 (a resistor, capacitor, etc.) are optionally disposed on the first substrate 110, and for further external electrical connection, an external terminal 40 may also optionally be disposed on the first substrate 110. In addition, the active device 10, the sensing element 20, the passive device 30, and the external terminal 40 may be bonded to the first conductive layer 112 of the substrate 110 through an eleventh bonding layer 10b, a twelfth bonding layer 20a, a thirteenth bonding layer 30a, and a fourteenth bonding layer 40a respectively. The eleventh bonding layer 10b, the twelfth bonding layer 20a, the thirteenth bonding layer 30a, and the fourteenth bonding layer 40a are similar to the first bonding layer 122c. Therefore, the same details will not be repeated in the following.

In FIG. 1A, the first power component 120 (corresponding to an area A1), the second power component (corresponding to an area A2), and the third power component 160 (corresponding to an area A3) are drawn in the same structure. However, the components shown in FIGS. 1B to 1D may also exist alone or be combined in pairs according to actual application requirements, or may even be used in conjunction with one or more power components in any of the following embodiments.

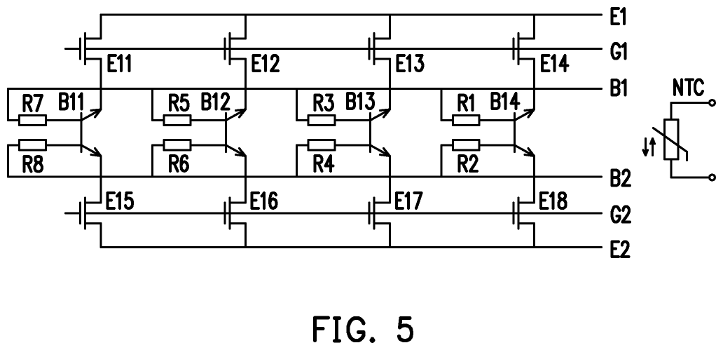

As an example of a circuit design, the power module package structure 100 may integrate 4 suitable power chips with a double-sided electrode (corresponding to a position B11, a position B12, a position B13, and a position B14 in FIG. 5), 8 suitable MOS (corresponding to a position E11, a position E12, a position E13, a position E14, a position E15, a position E16, a position E17, and a position E18 in FIG. 5), 8 suitable resistors (corresponding to a position R1, a position R2, a position R3, a position R4, a position R5, a position R6, a position R7, and a position R8 in FIG. 5), a suitable temperature sensing element (corresponding to a position NTC in FIG. 5), and a suitable emitter, gate, and base (corresponding to a position E1/position E2, a position G1/position G2, a position B1/position B2 in FIG. 5), and connect these components in series as shown in FIG. 5.

Reference numerals and descriptions from the aforementioned embodiment are applicable to subsequent embodiments as well. The same reference numerals represent identical or similar components, and descriptions of the same technical content will be omitted. For omitted details, refer to the descriptions in the aforementioned embodiment, as they will not be repeated in subsequent embodiments.

Referring to FIG. 6, compared to the power module package structure 100 in FIG. 1, a pin 251a of a second chip 251 of a second power component 250 of another power module package structure 200 in this embodiment extends downward (in a direction close to the substrate 110) to be connected to the fourth bonding layer 152c of the first spacing portion 152.

Referring to FIG. 7, compared to the power module package structure 100 in FIG. 1, a pin 351a of s second chip 351 of a second power component 350 of still another power module package structure 300 in this embodiment is a double-sided extended pin. That is, there are pins 351a extending from the package colloid (not shown) on two opposite sides of the second chip 351, and the pin 351a are correspondingly connected to the first spacing portion 152.

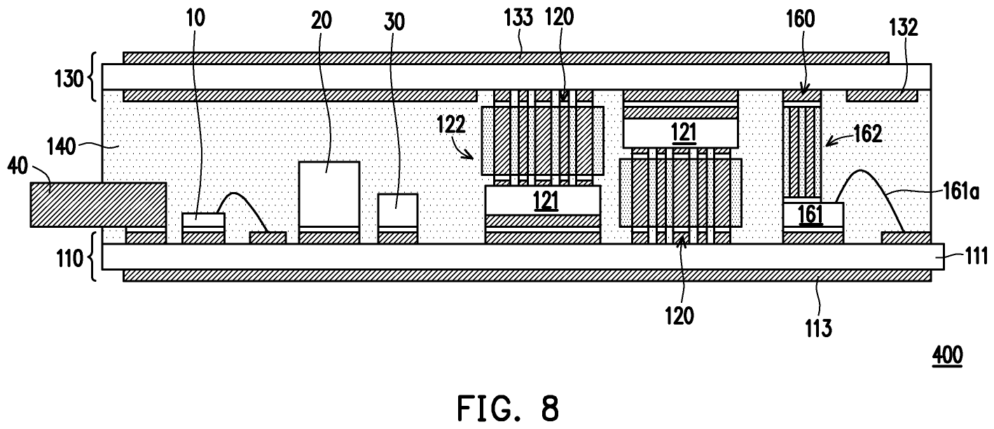

Referring to FIG. 8, compared to the power module package structure 100 in FIG. 1, a position of the second power component 150 of yet another power module package structure 400 in this embodiment is replaced with another first power component 120. The two first power components 120 have different directionality. For example, the first spacer 122 of the first power component 120 on the left in FIG. 8 is close to the second substrate 130, while the first spacer 122 of the first power component 120 on the right in FIG. 8 is close to the first substrate 110.

In this embodiment, the thicknesses of the first chip 121 and the third chip 161 may be between 0.05 mm and 0.5 mm. The metal on a front side thereof (e.g., facing the spacer 122) is titanium/nickel/silver, and the metal on a back side thereof (e.g., away from the first spacer 122) is titanium/nickel/silver. The metal on a front side of the third chip 161 (e.g., facing the first spacer 122) is aluminum, and the metal on a back side (e.g., away from the first spacer 122) is titanium/vanadium/nickel/silver. A length, width, and height of the sensing element 20 (a negative temperature coefficient thermistor) are 0.8 mm, 1.6 mm, and 0.8 mm respectively. A length, width, and height of the passive device 30 (the resistor) are 1 mm, 0.5 mm, and 0.35 mm respectively. A wire diameter of the wire bonder 161a is 1.5 mil. A length, width, and height of the spacer 122 are 3.5 mm, 3.5 mm, and 1.2 mm respectively, and the metal on two sides thereof is nickel respectively. Lengths, widths, and, heights of the substrate 110 and the substrate 130 are 12.5 mm, 12.5 mm, and 1.135 mm respectively, and the metal on two sides thereof is nickel. With such specification, the heat dissipation capacity may be improved while meeting electrical requirements.

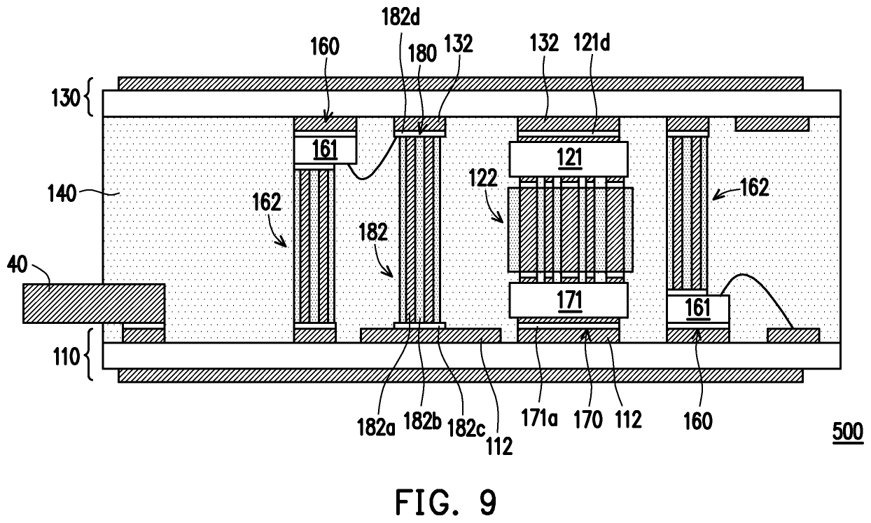

Referring to FIG. 9, compared to the power module package structure 100 in FIG. 1, still yet another power module package structure 500 in this embodiment only includes the first substrate 110, the second substrate 130, the package colloid 140, the two third power components 160 with different directionality, a fourth power component 170, and a heat dissipation component 180.

In this embodiment, the fourth power component 170 includes the first chip 121, the first spacer 122, and a fourth chip 171. The first spacer 122 is located between the first chip 121 and the fourth chip 171, and the first chip 121 is electrically connected to the fourth chip 171 through the first spacer 122. This flip-chip bonding method may shorten the circuit path. An electrode of the first chip 121 is electrically connected and thermally conducted to the third conductive layer 132 of the second substrate 130 through the second bonding layer 121d, and an electrode of the fourth chip 171 is electrically connected and thermally conducted to the first conductive layer 112 of the first substrate 110 through a fifteenth bonding layer 171a. On the other hand, the heat dissipation component 180 includes a fourth spacer 182, and the fourth spacer 182 is similar to the first spacer 122. That is, the fourth spacer 182 includes multiple fifth vertical conductive connectors 182a and a fifth insulating heat dissipation layer 182b. In addition, the fourth spacer 182 conducts heat to the first substrate 110 and the second substrate 130 respectively through a sixteenth bonding layer 182c and seventeenth bonding layer 182d thereof to further optimize the overall heat dissipation efficiency of the power module package structure 500. The fifteenth bonding layer 171a, the sixteenth bonding layer 182c, and the seventeenth bonding layer 182d are similar to the first bonding layer 122c. Therefore, the same details will not be repeated in the following.

The disclosure is not limited to the combination and configuration of the power components in the above power module package structure. According to the actual design requirements, the power module package structure may include only any one of the above power components or include other combinations and configurations not shown. As long as the spacers or spacing portions therein may be used as the conductive paths and heat dissipation paths, they all fall within the scope of protection of the disclosure.

The chip in the power module package structure herein may be any suitable power chip. For example, it may be a silicon-based power component (e.g., a bipolar transistor, an insulated gate bipolar transistor (IGBT), a metal oxide semiconductor field effect transistor (MOSFET), or the like), a compound power component (e.g., a silicon carbide chip, a gallium nitride chip, or the like), and each of the above power modules may be a high power module, a medium power module, or a low power module. The disclosure is not limited to a type and use of the power module package structure.

Based on the above, the power module package structure in the disclosure uses the spacer or the spacing portion as the conductive path and the heat dissipation path through the design of the power component. In this way, the heat dissipation capability may be improved while meeting the electrical requirements.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A power module package structure, comprising:
a first substrate comprising a surface and at least one conductive layer located on the surface; and
a power component comprising a first chip and a first spacer, wherein the first chip has at least one electrode, and the first spacer located in a heat dissipation space between the first substrate and the first chip comprises:
an insulating heat dissipation layer located in the heat dissipation space; and
a plurality of vertical conductive connectors, wherein each of the vertical conductive connectors penetrates the insulating heat dissipation layer, the insulating heat dissipation layer surrounds the vertical conductive connector and electrically isolates the vertical conductive connector, the vertical conductive connector comprises two opposite ends, one end is electrically connected to the conductive layer, and the other end is electrically connected to the electrode to form a conductive path and a heat dissipation path between the first chip and the first substrate.

2. The power module package structure according to claim 1, wherein the vertical conductive connector, the conductive layer, and the electrode are aligned with one another in a direction perpendicular to the surface of the first substrate.

3. The power module package structure according to claim 1, further comprising a second substrate, wherein the power component is located between the first substrate and the second substrate, and a side of the first chip opposite to the first spacer is electrically connected and thermally conducted to the second substrate.

4. The power module package structure according to claim 1, further comprising a package colloid encapsulating the power component and the conductive layer facing the first spacer in the first substrate.

5. The power module package structure according to claim 1, wherein an orthogonal projection of the first spacer on the first substrate overlaps an orthogonal projection of the first chip on the first substrate.

6. The power module package structure according to claim 1, wherein the first spacer comprises at least two bonding layers, and the at least two bonding layers are bonded to the first chip and the conductive layer respectively.

7. The power module package structure according to claim 6, wherein the at least two bonding layers are in direct contact with the first chip and the conductive layer respectively.

8. The power module package structure according to claim 1, wherein the power component further comprises a second chip located in the heat dissipation space, a pin connected to the second chip, and a second spacer adjacent to the second chip, the pin is electrically connected to the second chip and the second spacer, and the second spacer comprises the insulating heat dissipation layer and the vertical conductive connectors according to claim 1.

9. A power module package structure, comprising:
a first substrate; and
a power component located on the first substrate, wherein the power component comprises:
a first chip; and
a spacer connecting the first chip and the first substrate, wherein the spacer comprises a plurality of vertical conductive connectors and an insulating heat dissipation layer, the insulating heat dissipation layer is located in a heat dissipation space between the first substrate and the first chip and surrounds the vertical conductive connector to electrically isolate the vertical conductive connectors, and the vertical conductive connectors penetrate the insulating heat dissipation layer to be electrically connected to the first chip and the first substrate.

10. The power module package structure according to claim 9, wherein the insulating heat dissipation layer is formed by an insulating organic material, and the insulating organic material comprises aluminum nitride, copper molybdenum, aluminum silicon carbide, aluminum oxide, and silicon nitride, or a combination thereof.

11. The power module package structure according to claim 10, wherein the vertical conductive connectors are a plurality of metal pillars.

12. The power module package structure according to claim 11, wherein the metal pillars are correspondingly attached to a plurality of electrodes on the first chip.

13. The power module package structure according to claim 9, wherein the power component further comprises a second chip, wherein the spacer is located between the first chip and the second chip, and the first chip is electrically connected and thermally conducted to the second chip through the spacer.

14. A power module package structure, comprising:
a conductive layer;
a first substrate located at a position opposite to the conductive layer; and
a power component located on the first substrate and comprising:
a chip located in a heat dissipation space between the conductive layer and the first substrate;
at least one pin electrically connected to the chip;
a first spacing portion adjacent to the chip, and comprising a plurality of vertical conductive connectors electrically connected to the pin and an insulating heat dissipation layer surrounding the vertical conductive connectors, wherein the vertical conductive connectors penetrate the insulating heat dissipation layer to form a conductive path between the chip and the first substrate; and
a second spacing portion located on the chip, and comprising a plurality of vertical conductive connectors electrically connected to the chip and the conductive layer and an insulating heat dissipation layer surrounding the vertical conductive connectors, wherein the vertical conductive connectors penetrate the insulating heat dissipation layer to form a heat dissipation path between the conductive layer and the chip.

15. The power module package structure according to claim 14, wherein the first spacing portion is respectively bonded to the pin and the first substrate through at least two bonding layers.

16. The power module package structure according to claim 14, wherein there is no thermal conduction between the first spacing portion and the chip, and there is no electrical connection between the second spacing portion and the chip.

17. The power module package structure according to claim 14, further comprising a second substrate, wherein the conductive layer is comprised in the second substrate, and the second spacing portion extends from the chip to the second substrate.

18. The power module package structure according to claim 14, further comprising a first package colloid encapsulating the power component and the conductive layer facing the chip in the first substrate.

19. The power module package structure according to claim 14, wherein the first spacing portion is located at different level heights.

20. The power module package structure according to claim 14, wherein the first spacing portion and the second spacing portion are connected to different surfaces of the chip.
